(19) United States
(12) Patent Application Publication
(10) Pub. No.: US 2023/0317689 A1
(43) Pub. Date: Oct. 5, 2023

(54) Package-on-Package Assembly with Improved Thermal Management

(71) Applicant: Google LLC, Mountain View, CA (US)

(72) Inventors: Mengzhi Pang, Cupertino, CA (US); Ashish Jain, Belmont, CA (US)

(73) Assignee: Google LLC, Mountain View, CA (US)

(21) Appl. No.: 18/041,621

(22) PCT Filed: Aug. 17, 2021
(86) PCT No.: PCT/US2021/046238

§ 371 Date: Feb. 14, 2023

Related U.S. Application Data
(60) Provisional application No. 63/067,686, filed on Aug. 19, 2020.

(51) Int. Cl. H01L 25/10; H01L 23/373; H01L 23/00; H01L 23/31; H01L 23/498

(52) U.S. Cl. CPC H01L 25/105; H01L 23/3736; H01L 24/32; H01L 23/3128; H01L 23/49822; H01L 2224/32245; H01L 2225/1058

(57) ABSTRACT

Techniques and apparatuses for a package-on-package (PoP) assembly with improved thermal management are described. In aspects, the PoP assembly includes a first IC package comprising a first IC die and a second IC package comprising a second IC die. The PoP assembly can be configured with various thermal management components that spread or dissipate heat generated by the first IC die or the second IC die of the PoP assembly. These thermal management components may include a heat spreader encapsulated within the first IC package, dummy silicon encapsulated within the first IC package, and/or a plurality of solder interconnects between the first IC package and the second IC package. By including one or more of these thermal management components, the described PoP assembly may improve thermal management of the IC packages of the PoP assembly and enable increased IC die performance or reliability over preceding assembly designs.

### BACKGROUND

To conserve space and achieve performance targets of silicon-based integrated circuits (ICs), semiconductor assembly techniques often use a stacking approach to manufacture a semiconductor IC package known as a package-on-package (PoP) assembly. A PoP assembly may include multiple IC packages stacked vertically, with each IC package including one or more silicon IC die. This vertical stacking of IC packages may reduce a footprint of the PoP assembly. However, thermal performance of the respective silicon die within the stacked IC packages may be impaired or degraded.

For example, a PoP assembly is typically formed with materials or configurations that are detrimental to dissipating heat and maintaining a desirable junction temperature of a silicon IC die (e.g., a system-on-chip (SoC) IC die). In some cases, the PoP assembly includes an air gap between a first IC package and a second IC package, effective to inhibit transfer of heat, originating from a silicon IC die of the first package, from the first IC package to the second IC package. Furthermore, the silicon IC die of the first IC package may have a high percentage of surface area that is in direct contact with a mold compound with low thermal-conductivity properties, inhibiting heat transfer originating within the silicon IC die to the second IC package or an external environment for eventual dissipation. When heat transfer away from the silicon IC is inhibited, a junction temperature of the silicon IC may increase due to high-power operating conditions. If a threshold for the junction temperature is exceeded under such operating conditions, speed performance and/or reliability of the silicon IC die within the PoP assembly may be compromised.

### SUMMARY

Techniques and apparatuses are described that provide thermal management of a package-on-package (PoP) assembly. In aspects, the PoP assembly includes a first IC package comprising a first IC die (e.g., SoC die) and a second IC package comprising a second IC die (e.g., memory die). The PoP assembly can be configured with various thermal management components that spread or dissipate heat generated by the first IC die or the second IC die of the PoP assembly. These thermal management components may include a heat spreader encapsulated within the first IC package, dummy silicon encapsulated within the first IC package, and/or a plurality of solder interconnects between the first IC package and the second IC package. By including one or more of these thermal management components, the described PoP assembly may improve thermal management (e.g., power dissipation) of the IC packages of the PoP assembly, which may, in turn, provide increased IC die performance or reliability.

In some aspects, a PoP assembly includes a first integrated circuit package comprising a first integrated circuit die and a second integrated circuit package comprising a second integrated circuit die, the second integrated circuit package being coupled to the first integrated circuit package. The PoP assembly also includes a thermal management component encapsulated in the first integrated circuit package and in thermal contact with the first integrated circuit die, the thermal management component comprising a heat spreader configured to spread heat from the first integrated circuit die throughout the first integrated circuit package for transfer to the second integrated circuit package.

In other aspects, a PoP assembly includes a first integrated circuit package comprising a first integrated circuit die and a second integrated circuit package comprising a second integrated circuit die, the second integrated circuit package being coupled to the first integrated circuit package. The PoP assembly also includes thermal management components encapsulated in the first integrated circuit package, the thermal management components including at least two dummy silicon components disposed adjacent to respective sides of the first silicon integrated circuit die and configured to spread heat from the first integrated circuit die throughout the first integrated circuit package for transfer to the second integrated circuit package.

In yet other aspects, a PoP assembly includes a first integrated circuit package comprising a first integrated circuit die and a second integrated circuit package comprising a second integrated circuit die, the second integrated circuit package being coupled to the first integrated circuit package. The PoP assembly also includes thermal management components disposed between and in thermal contact with the first integrated circuit package and the second integrated circuit package, the thermal management components including a plurality of solder interconnects with a subset of the solder interconnects configured to transfer heat from the first integrated circuit package to the second integrated circuit package.

The details of one or more implementations are set forth in the accompanying drawings and the following description. Other features and advantages will be apparent from the description, the drawings, and the claims. This summary is provided to introduce subject matter that is further described in the Detailed Description. Accordingly, a reader should not consider the summary to describe essential features nor limit the scope of any claimed subject matter.

### BRIEF DESCRIPTION OF THE DRAWINGS

Apparatuses of and techniques for thermal management of a package-on-package (PoP) IC package are described with reference to the following drawings. The same numbers are used throughout the drawings to reference like features and assemblies:

FIG. 1 illustrates an example environment in which aspects of thermal management of a PoP assembly can be implemented;

FIG. 2 illustrates example devices in which a PoP assembly can be implemented in accordance with one or more aspects;

FIG. 3 illustrates an example PoP assembly implemented with a heat spreader encapsulated in an SoC IC package;

FIG. 4 illustrates an example PoP assembly implemented with an array of solder interconnects between a memory IC package and an SoC IC package;

FIG. 5 illustrates an example PoP assembly implemented with dummy silicon encapsulated in an SoC IC package;

FIG. 6 illustrates a plan view of an example PoP assembly that includes dummy silicon encapsulated in an SoC IC package; and

FIG. 7 illustrates example method(s) for forming a PoP assembly with one or more thermal management components in accordance with one or more aspects.

### DETAILED DESCRIPTION

This document describes apparatuses of and techniques for thermal management of a package-on-package (PoP) package (e.g., PoP chip package). In preceding PoP assembly designs, a PoP assembly typically included several features that inhibited heat spreading and/or heat flow throughout the PoP assembly. By way of example, these PoP assemblies often included an air gap between IC packages of the PoP assembly. Air, in general, has low thermal-conductivity (e.g., 0.024 Watts per meter Kelvin, or W/m·K), which inhibits heat flow. Additionally, IC die of the PoP assemblies are typically encapsulated in a mold compound, which generally also has a low thermal-conductivity (e.g., 0.88 W/m·K) that inhibits heat flow. Thus, the air gap and/or the mold compound present in preceding PoP assemblies may inhibit heat flow from the IC die through the PoP assembly and ultimately to a surrounding environment. When heat transfer away from the IC die is inhibited, a junction temperature of the IC die may increase due to sustained or high-power operating conditions. If a threshold for the junction temperature is exceeded under such operating conditions, speed performance and/or reliability of the IC die within the PoP assembly may be compromised.

In contrast with preceding designs, this disclosure describes aspects of a PoP assembly with improved thermal management. In aspects, a PoP assembly with improved thermal management includes a first IC package comprising a first IC die (e.g., SoC die) and a second IC package comprising a second IC die (e.g., memory die). The described PoP assembly can be configured with various thermal management components that spread or dissipate heat generated by the first IC die or the second IC die of the PoP assembly. Generally, the heat generated by the first IC and/or the second IC may be spread away from the ICs or throughout the PoP assembly, enabling more efficient heat transfer or reducing an operating temperature (e.g., junction temperature) of at least one of the ICs. These thermal management components may include a heat spreader encapsulated within the first IC package, dummy silicon encapsulated within the first IC package, and/or a plurality of solder interconnects between the first IC package and the second IC package. By including one or more of these thermal management components, the described PoP assembly may improve thermal management (e.g., power dissipation) of the IC packages of the PoP assembly, which may, in turn, results in increased IC die performance or reliability.

In some cases, the described techniques and apparatuses of improved thermal management may enable an IC die to maintain a junction temperature at or below a desired temperature threshold under a sustained or a high-power loading condition. For example, the PoP assembly, when configured with one or more thermal management components, may effectively maintain a junction temperature of the IC die (e.g., SoC die) at or below 105 degrees Celsius (° C.) under a thermal loading condition that exceeds 3 Watts (W). By so doing, throttling of the IC die to operate at a lower clock frequency in response to thermal conditions (e.g., exceeded thermal limits) may be avoided. Thus, improving thermal management of a PoP assembly may enable IC die and PoP assembly designers to better achieve temperature-related performance targets.

While features and concepts described herein may be implemented in any number of different environments, assemblies, systems, devices, and/or various configurations, aspects of a PoP assembly with improved thermal management are described in the context of the following example environment, devices, configurations, assemblies, and methods.

### Example Environment

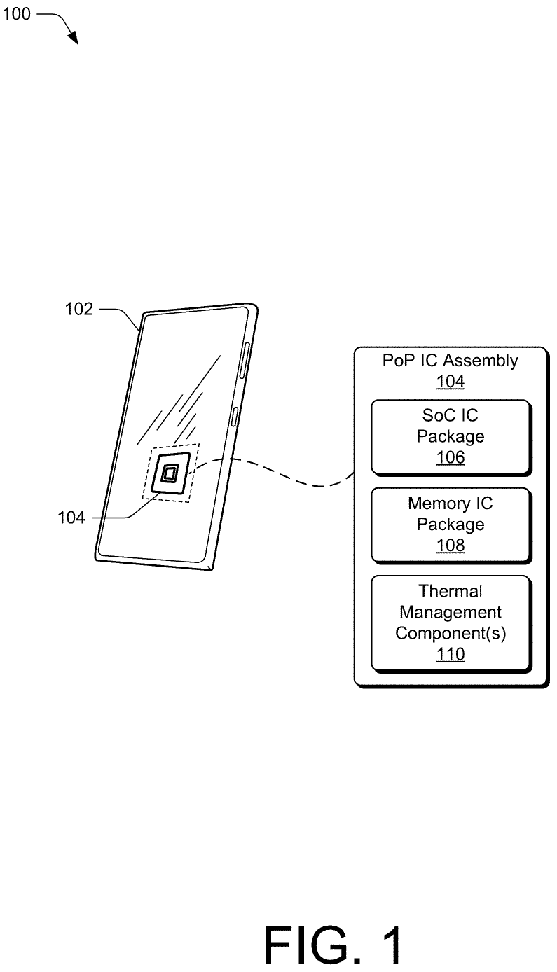

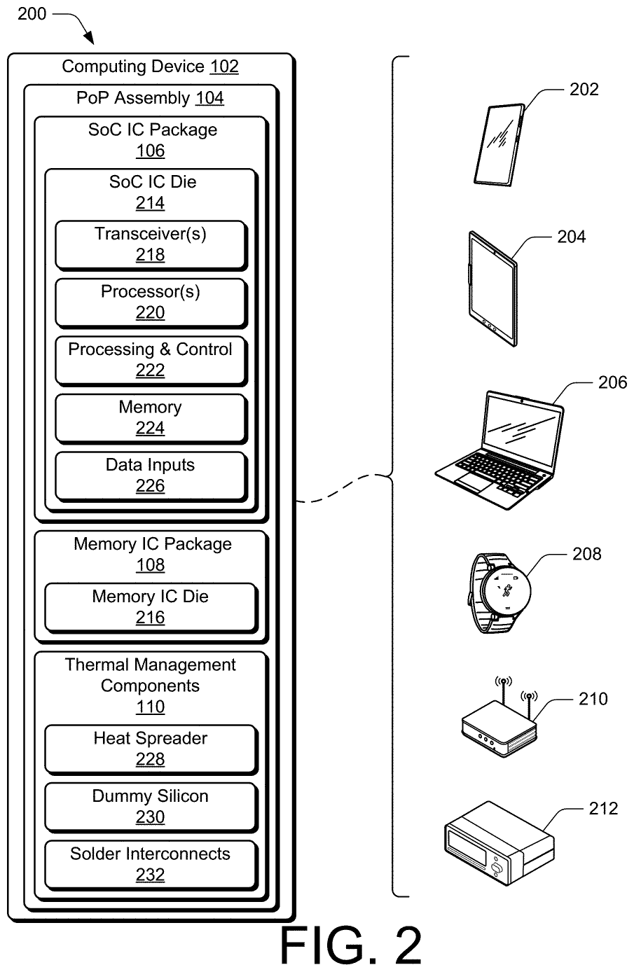

FIG. 1 illustrates an example environment 100 in which a PoP assembly with improved thermal management can be implemented. In FIG. 1, a computing device 102 (e.g., a user equipment (UE) capable of wireless communication) includes various hardware and components, including a PoP assembly 104. Although illustrated as a smartphone, the computing device 102 may be implemented as any suitable electronic device or user device, including those described with reference to FIG. 2.

In aspects, The PoP assembly 104 may include multiple IC packages that may include two or more assembled IC packages, with each assembled IC package including one or more IC die. As illustrated in FIG. 1, the PoP assembly 104 includes an SoC IC package 106 and a memory IC package 108. The PoP assembly 104 also includes at least one thermal management component 110, which may be implemented in or coupled with one of the SoC IC package 106 and/or memory IC package 108 as described herein.

### Example Device

FIG. 2 illustrates a device diagram 200 of a computing device 102 that includes a PoP assembly 104 configured in accordance with one or more aspects. The example computing device 102 may be implemented as any suitable device, some of which are illustrated as a smartphone 202, a tablet computer 204, a laptop computer 206, a wearable computing device 208 (e.g., smart-watch), a set-top box 210 (e.g., media device or mobile hotspot), and automotive computing system 212 (e.g., navigation and entertainment system). Although not shown, the computing device 102 may also be implemented as any of a mobile station (e.g., fixed- or mobile-STA), a user equipment (UE), a mobile communication device, a user device, a client device, a mobile phone, an entertainment device, a gaming device, a mobile gaming console, a personal media device, a media playback device, an advanced driver assistance system (ADAS), a point-of-sale (POS) transaction system, a health monitoring device, a drone, a camera, a wearable smart-device, a navigation device, a MID, an Internet home appliance capable of wireless Internet access and browsing, an IoT device, and/or other types of user devices. The computing device 102 may include additional functions, components (e.g., a display or keyboard), or interfaces omitted from FIG. 2 for the sake of clarity or visual brevity.

In aspects, the PoP assembly 104 enables various functionalities of the computing device 102, which may include one or more processing, communication, and/or data storage functions. Generally, the PoP assembly 104 includes multiple IC packages or chips that include respective ICs or IC die. The multiple IC packages of the PoP assembly 104 may be mechanically, thermally, and/or electrically coupled with one another within the PoP assembly. For example, a PoP assembly 104 may include a processing chip, a memory chip (e.g., dynamic random-access memory (DRAM) package), a communication chip (e.g., wireless modem package), a sensor chip, and so forth, which are communicatively coupled with each other to provide an embedded system of a computing device 102. Alternatively or additionally, two or more processing or sub-systems of the PoP assembly 104 may be integrated on a die to provide a system-on-chip (SoC). Although described with reference to die- or SoC-based packaging, the components of a PoP assembly 104 shown in FIG. 2 may be embodied as other systems or component configurations, such as, and without limitation, a Field-Programmable Gate Array (FPGA), an Application-Specific Integrated Circuit (ASIC), an Application-Specific Standard Product (ASSP), a digital signal processor (DSP), Complex Programmable Logic Devices (CPLD), system in package (SiP), package on package (PoP), processing and communication chipset, communication co-processor, sensor co-processor, or the like.

In the example shown at 200, the PoP assembly 104 includes an SoC IC package 106, a memory IC package 108, and thermal management components 110 that are implemented in accordance with aspects of improved thermal control for a PoP assembly. Although not shown, the PoP assembly 104 may be implemented with additional or different combinations of IC packages, including input/output (I/O) IC packages, power management IC packages, communication IC packages, and so forth. In aspects, the SoC IC package 106 includes an SoC IC die 214 and the memory IC package 108 includes a memory IC die 216. The memory IC die 216 of the memory IC package 108 may include memory circuitry (e.g., process-readable storage media) configured as any suitable type of hardware-based memory or storage device such as random-access memory (RAM), static RAM (SRAM), dynamic RAM (DRAM), non-volatile RAM (NV-RAM), read-only memory (ROM), or Flash memory usable to store data or instructions of the SoC IC die 214. In some cases, the memory IC die 216 is configured as a low-power double data rate dynamic random-access memory (LPDDR5 DRAM) IC die.

In this example, the SoC IC die 214 communication transceivers 218 (transceivers 218) that enable wired or wireless communication of data or control information. In some aspects, the transceivers 218 includes a wireless modem or baseband processor that is configurable to communicate in accordance with various communication protocols and/or in different frequency bands. The transceivers 218 may include a transceiver interface (not shown) for communicating encoded or modulated signals with transceiver circuitry. The SoC IC die 214 includes one or more processors 220 (or processor cores), which process various computer-executable instructions to control the operation of the SoC IC die 214 and to enable functionalities of a computing device 102 in which the PoP assembly is embodied. Alternatively or additionally, the SoC IC die 214 can be implemented with any one or combination of hardware, firmware, or fixed logic circuitry that is implemented in connection with processing and control circuits, which are generally shown at 222. Although not shown, the SoC IC die 214 may also include a bus, interconnect, crossbar, or fabric that couples the various components within the SoC IC die 214.

The SoC IC die 214 also includes a memory 224 (e.g., computer-readable media), such as one or more memory circuits that enable persistent and/or non-transitory data storage, and thus do not include transitory signals or carrier waves. Examples of the memory 224 include RAM, SRAM, DRAM, NV-RAM, ROM, EPROM, or Flash memory. The memory 224 provides data storage for data of the SoC IC die 214 (e.g., system data), as well as for firmware, applications, and any other types of information and/or data related to operational aspects of the SoC IC die 214. The SoC IC die 214 may also include one or more data inputs 226 via which any type of data, media content, and/or inputs can be received, such as user input, user-selectable inputs (explicit or implicit), or any other type of audio, video, and/or image data received from a content and/or data source. Alternatively or additionally, the data inputs 226 may include various data interfaces, which can be implemented as any one or more of a serial and/or parallel interface, a wireless interface, a network interface, and as any other type of communication interface enabling communication with other devices or systems. In aspects, the data inputs 226 include an electrical interface to the memory IC package 108 to enable the transfer of data and/or instructions between the SoC IC die 214 and the memory IC die 216.

In aspects, the PoP assembly 104 includes one or more thermal management components 110 that are implemented as part of or coupled with an IC package of the PoP assembly. As shown in FIG. 2, the thermal management components 110 of a PoP assembly 104 may include a heat spreader 228, dummy silicon 230, and solder interconnects 232, which may be implemented individually or in combination in accordance with one or more of the aspects described herein. In some implementations, a heat spreader 228 is encapsulated in the SoC IC package 106 and in thermal contact with the SoC IC die 214 and is configured to spread heat from the SoC IC die 214 throughout the SoC IC package 106 to enable transfer of the heat to the memory IC package 108. In other implementations, dummy silicon 230 is disposed adjacent to respective sides of the SoC IC die 214 and configured to spread heat from the SoC IC die 214 throughout the SoC IC package 106 to enable transfer of the heat to the memory IC package 108. In yet other implementations, a plurality of solder interconnects 232 are disposed between the SoC IC package 106 and the memory IC package 108 and include a subset of solder interconnects configured to transfer heat from the SoC IC package 106 to the memory IC package 108. In aspects, a PoP assembly 104 may be implemented with one or more thermal management components 110 to improve thermal performance (e.g., power dissipation) of the IC packages within the PoP assembly, which may, in turn, result in increased IC die performance or reliability.

### Example Package-on-Package Assemblies with Improved Thermal Management

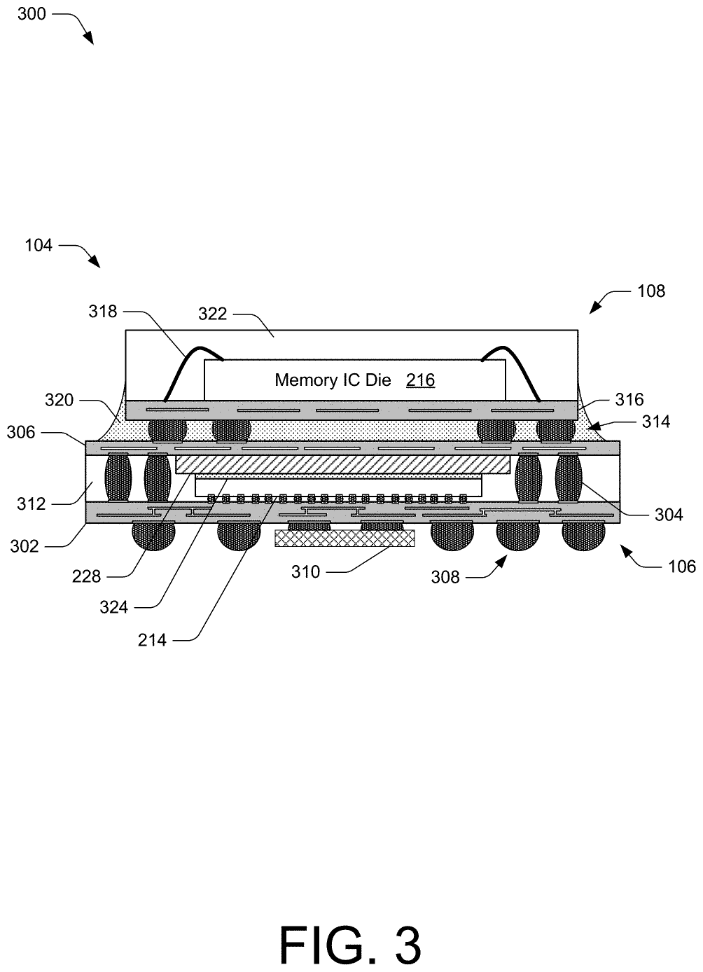

FIGS. 3-6 illustrate example configurations of a PoP assembly 104 with improved thermal management in accordance with one or more aspects. The aspects described with reference to any of the example configurations may be implemented individually or combined with other aspects described with reference to one or more of the other example configurations. As such, a PoP assembly may be implemented with a heat spreader encapsulated within a first IC package, dummy silicon encapsulated within a first IC package, and/or a plurality of solder interconnects between a first IC package and a second IC package in accordance with aspects of improved thermal management.

FIG. 3 illustrates at 300 an example PoP assembly 104 implemented with a heat spreader encapsulated in an SoC IC package. Generally, the PoP assembly 104 may be implemented with at least two IC packages that are stacked vertically such that a first IC package is disposed at least partially over a second IC package. In the example shown at 300, the PoP assembly 104 includes an SoC IC package 106 that is coupled with a memory IC package 108. In aspects, the memory IC package 108 may include or function as external memory (e.g., LPDDR5) for the SoC IC package 106. In some cases, an SoC IC die 214 of the SoC IC package 106 includes a high-power component (e.g., processor or graphics processing unit) that generates more heat than other components (e.g., a memory IC) within the PoP assembly 104. Accordingly, aspects of improved thermal management may spread heat from the SoC IC die 214 throughout the SoC IC package 106 for transfer to the memory IC package 108 and/or a substrate (e.g., device main logic board) to which the PoP assembly 104 is coupled. This transferred heat can then be more effectively dissipated to a surrounding environment of the PoP assembly 104, thereby reducing an operating temperature of the SoC IC die 214, which in turn may enable increased performance and improved reliability of the SoC IC die.

The SoC IC package 106, as illustrated, may include multiple features, including the SoC IC die 214 that is coupled to a first substrate 302 of the SoC IC package. The first substrate 302 may include a redistribution layer (RDL) with solder pads on respective sides and internal layers (e.g., traces and vias) to translate or provide respective coupling contacts for multiple sets of interconnects with different footprints (e.g., for ICs or structural components), pitch, density, types (e.g., ball grid or wire contacts), and combinations thereof. In this example, a first side of the first substrate 302 includes solder pads configured to support an array of solder interconnects (e.g., micro ball grid array (μBGA)) that couple the SoC IC die 214 to the substrate and to support solder interconnects 304 (e.g., solder balls, solder pillars, copper pillars, or the like) that couple the first substrate 302 to a first side of a second substrate 306 of the SoC IC package 106. A second side of the first substrate 302 includes solder pads configured to support an array of solder interconnects 308 (e.g., BGA) to couple the SoC IC package 106 or the PoP assembly 104 to another substrate, which may include a printed circuit board (PCB) or main logic board of the device in which the PA is embodied. In some cases, some of the solder pads or solder interconnects 308 of the second side of the first substrate 302 are coupled with a heat spreader 310 disposed on an exterior surface of the PoP assembly 104, which may improve heat transfer to a substrate to which the PA is mounted or coupled. In aspects, a mold compound 312 encapsulates components of the SoC IC package 106, which may include the SoC IC die 214, solder interconnects 304, and/or one or more thermal management components 110 as described herein.

To form the PoP assembly 104, the memory IC package 108 may be coupled to a second side of the second substrate 306 of the SoC IC package 106. The second substrate 306 may include a redistribution layer (RDL) with solder pads on respective sides and internal layers (e.g., traces and vias) to translate or provide respective coupling contacts for multiple sets of interconnects with different footprints (e.g., for ICs or structural components), pitch, density, types (e.g., ball grid or wire contacts), and combinations thereof. In this example, the first side of the second substrate 306 includes solder pads configured to support the solder interconnects 304 that couple the second substrate 306 to the first side of the first substrate 302. A second side of the second substrate 306 includes solder pads configured to support solder interconnects 314 (e.g., BGA, solder balls, solder pillars) to couple the SoC IC package 106 to the memory IC package 108. In some cases, the solder interconnects 314 are implemented as a partial array of solder interconnects, with the solder interconnects electrically, mechanically, and/or thermally coupling the SoC IC package 106 to the memory IC package 108. As shown in FIG. 3, the solder interconnects 314 are disposed between the second side of the second substrate 306 of the SoC IC package 106 and a first side of a substrate 316 of the memory IC package 108.

The memory IC package 108, as illustrated, may include multiple features, including the memory IC die 216 that is coupled to the substrate 316 of the memory IC package 108. The substrate 316 may include a redistribution layer (RDL) with solder pads on respective sides and internal layers (e.g., traces, vias) to translate or provide respective coupling contacts for multiple sets of interconnects with different footprints (e.g., for ICs or structural components), pitch, density, types (e.g., ball grid or wire contacts), and combinations thereof. In this example, a first side of the substrate 316 includes solder pads configured to support an array of solder interconnects (e.g., BGA) that couples the memory IC package 108 to the SoC IC package 106. A second side of the substrate 316 of the memory IC package 108 includes solder pads or contacts to support multiple bond wires 318 that electrically couple the memory IC die 216 to the substrate 316 and thus the SoC IC package 106. Generally, the solder interconnects and/or substrates (e.g., RDLs) may transmit electrical signaling (e.g., data, clocking) between integrated circuitry of the memory IC package 108 (e.g., the LPDDR5 DRAM die), the SoC IC package 106 (e.g., the SoC IC die), and/or a substrate (main logic board) to which the PoP assembly 104 is coupled. Alternatively, when implemented as part of a thermal management component, a solder interconnect may provide thermal coupling between IC packages without enabling electrical connectivity. In aspects, the components of the memory IC package 108, which may include the memory IC die 216 and bond wires 318, may be encapsulated with a mold compound 322. In some cases, the PoP assembly 104 may also include an underfill compound 320 disposed between the SoC IC package 106 and the memory IC package 108. The underfill compound 320 may have a higher thermal conductivity than another medium (e.g., air) effective to improve heat transfer characteristics within or throughout the PoP assembly 104 (e.g., between the SoC IC package 106 and the memory IC package 108).

In aspects of improved thermal management, the SoC IC package 106 includes a heat spreader 228 that is thermally coupled (e.g., in thermal contact) with the SoC IC die 214 and encapsulated in the mold compound 312 of the SoC IC package. The heat spreader 228 may include, for example, a metallic material (e.g., copper), semiconductor metallic (e.g., silicon), or the like, that is attached to or coupled with the SoC IC die 214 using a die attach film 324 (DAF 324). The die attach film 324 may include a conductive film, high-heat film, non-conductive film, or the like that facilitates a transfer of heat from the SoC IC die 214 to the heat spreader 228. In general, a surface area of the SoC IC die that is in contact with the mold compound of the SoC IC package 106 may be reduced by implementing such an encapsulated heat spreader.

In some cases, and to accommodate the heat spreader 228, a thickness of the SoC IC die 214 may be reduced from approximately 100 μm to approximately 50 μm. Alternatively or additionally, the heat spreader 228 may have a thickness that measures approximately 50 μm. By configuring the SoC IC die 214 with a reduced height, the SoC IC package 106 may be implemented with the heat spreader 228 without increasing an overall height of the SoC IC package and/or the PoP assembly 104. In aspects, the heat spreader 228 may enhance spreading heat that originates from the SoC IC die 214 laterally throughout SoC IC package 106 for transfer to the memory IC package 108 and the memory IC die 216 within. This enhanced spreading of the heat away from the SoC IC die 214 may reduce an operating temperature of the SoC IC die under a given workload, thereby increasing performance or improving reliability of the SoC IC die at one or more operating frequencies.

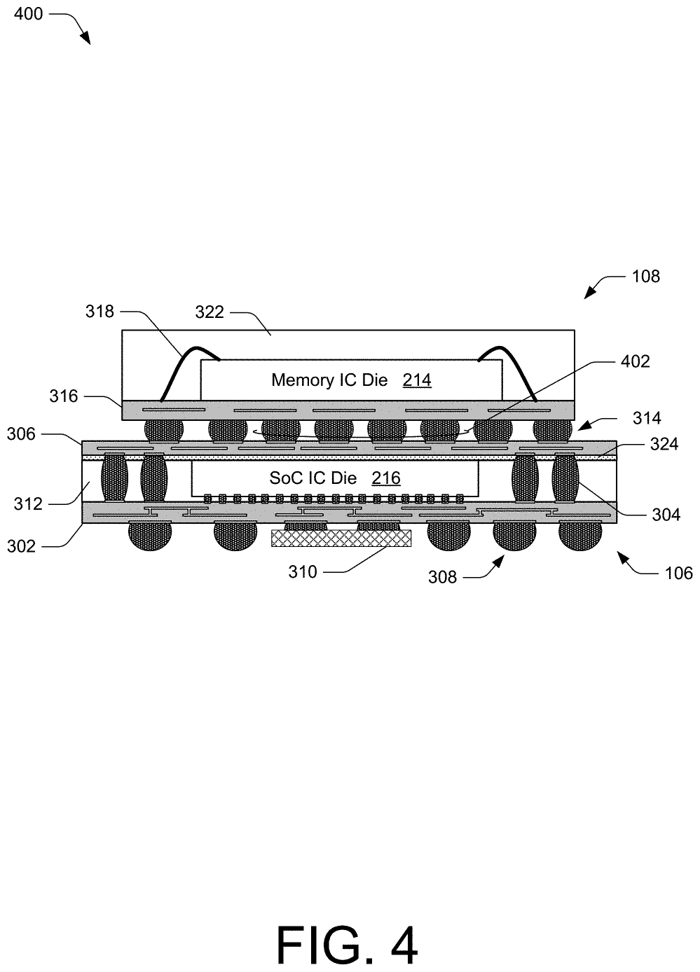

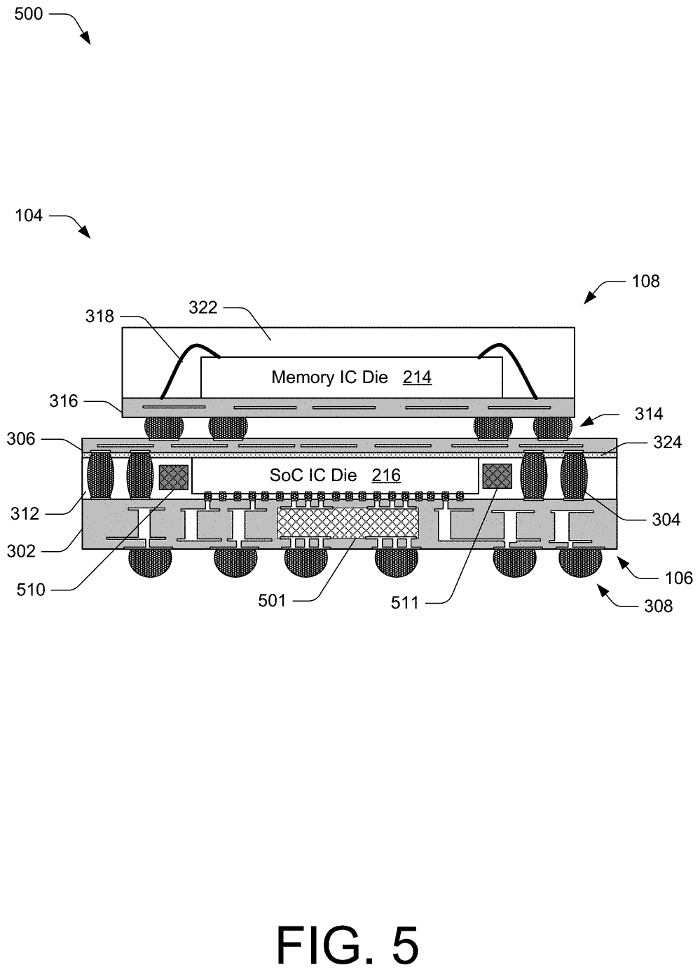

FIG. 4 illustrates at 400 an example PoP assembly 104 implemented with an array of solder interconnects between a memory IC package and an SoC IC package. The PoP assembly 104 of FIG. 4 may be implemented similar to or different from the PoP assembly 104 of FIG. 3 or the PoP assembly 104 of FIG. 5, with like components referred to using a same number and/or description. For the sake of brevity, description of some similar components or configurations of this example PoP assembly 104 may be omitted. In the example shown at 400, the PoP assembly 104 includes an SoC IC package 106 that is coupled with a memory IC package 108. In aspects, the SoC IC package 106 includes an SoC IC die 214 that is coupled to a second substrate 306 of the SoC IC package 106 via a die attach film 324, which may include a conductive film, high-heat film, non-conductive film, or the like that facilitates a transfer of heat from the SoC IC die 214 to the second substrate 306 and/or the memory IC package 108. In some cases, the SoC IC die is configured with a thickness of approximately 100 μm and is disposed between the first substrate 302 and the second substrate 306 of the SoC IC package 106.

In aspects, the PoP assembly 104 is implemented with a thermal management component 110 that includes a subset of solder interconnects 402 disposed between the SoC IC package 106 and the memory IC package 108. Thus, an array of solder interconnects 314 may be implemented as a full array of solder interconnects (e.g., a plurality of interconnects) may be disposed between IC packages of the PoP assembly 104. However, and in contrast to the PoP assemblies that include a peripheral (or paritial) array of solder interconnects along an edge, outline, or periphery of the memory IC package 108 (e.g., as illustrated in FIG. 3), the full array of solder interconnects includes a subset of interconnects 402 that is specifically included to transfer heat from the SoC IC package 106 to the memory IC package 108. In other words, the subset of solder interconnects 402 may transfer heat from one IC package to another IC package but not electrical signals. When implemented with the subset of solder interconnects 402, heat originating from the SoC IC die 214 may flow throughout the SoC IC package 106 and transfer to the memory IC package 108. In some cases, this transfer of heat to the memory IC package may include transferring the heat to an LPDDR5 IC die of the memory IC package 108. While not shown in FIG. 4, the SoC IC package 106 may further comprise a heat spreader 228 as shown in FIG. 3.

FIG. 5 illustrates at 500 an example PoP assembly 104 implemented with dummy silicon encapsulated in an SoC IC package. The PoP assembly 104 of FIG. 5 may be implemented similar to or different from the PoP assembly 104 of FIG. 3 or the PoP assembly 104 of FIG. 4, with like components referred to using a same number and/or description. For the sake of brevity, description of some similar components or configurations of this example PoP assembly 104 may be omitted. In the example shown at 500, the PoP assembly 104 includes an SoC IC package 106 that is coupled with a memory IC package 108. In aspects, the SoC IC package 106 includes an SoC IC die 214 that is coupled to a second substrate 306 of the SoC IC package 106 via a die attach film 324, which may include a conductive film, high-heat film, non-conductive film, or the like that facilitates a transfer of heat from the SoC IC die 214 to the second substrate 306 and/or the memory IC package 108. In some cases, the SoC IC die is configured with a thickness of approximately 100 μm and is disposed between the first substrate 302 and the second substrate 306 of the SoC IC package 106. Here, the first substrate 302 of the SoC IC package 106 includes an internal or embedded heat spreader 502 (e.g., copper material, silicon material), which may enhance heat transfer from the SoC IC die 214 through the first substrate 302 to the solder interconnects 308 and another substrate to which the PoP assembly 104 is coupled. Although shown in FIG. 5, an internal heat spreader 502 may be implemented in any substrate of an IC package of the PoP assembly 104, which may include substrate 302, 306, 316, or so forth.

In aspects of improved thermal management, the SoC IC package 106 of the PoP assembly 104 can be implemented with dummy silicon components 510, 511 disposed proximate one or more sides of the SoC IC die 214. These dummy silicon components may be encapsulated in the mold compound 312 with other components of the SoC IC package 106, including the SoC IC die 214 and solder interconnects 304. In this example, the SoC IC package 106 includes a first dummy silicon component 510 and a second dummy silicon component 511 disposed proximate respective sides of the SoC IC die 214. The dummy silicon components 510, 511 (e.g., additional silicon) may include no integrated circuitry and may displace mold compound that may otherwise be part of the SoC IC package. The dummy silicon may have a thickness (e.g., Z-thickness, normal to the XY plane) that is greater than, less than, or equal to that of the SoC IC die 214. In contrast to the mold compound, the dummy silicon has a relatively high thermal conductivity (e.g., 150 W/m·K in contrast to 0.88 W/m·K). Thus, adding the dummy silicon components to the SoC IC package 106 may enhance the transfer of heat from the SoC IC die 214 throughout the SoC IC package 106 and subsequently to the memory IC package 108 and/or a substrate to which the PoP assembly 104 is coupled via the solder interconnects 308 or a heat spreader disposed on the underside of the PoP assembly 104. While not shown in FIG. 5, the SoC IC package 106 may further comprise a heat spreader 228 as shown in FIG. 3, and/or the PoP assembly 104 may further comprise the subset of solder interconnects 402 as shown in FIG. 4.

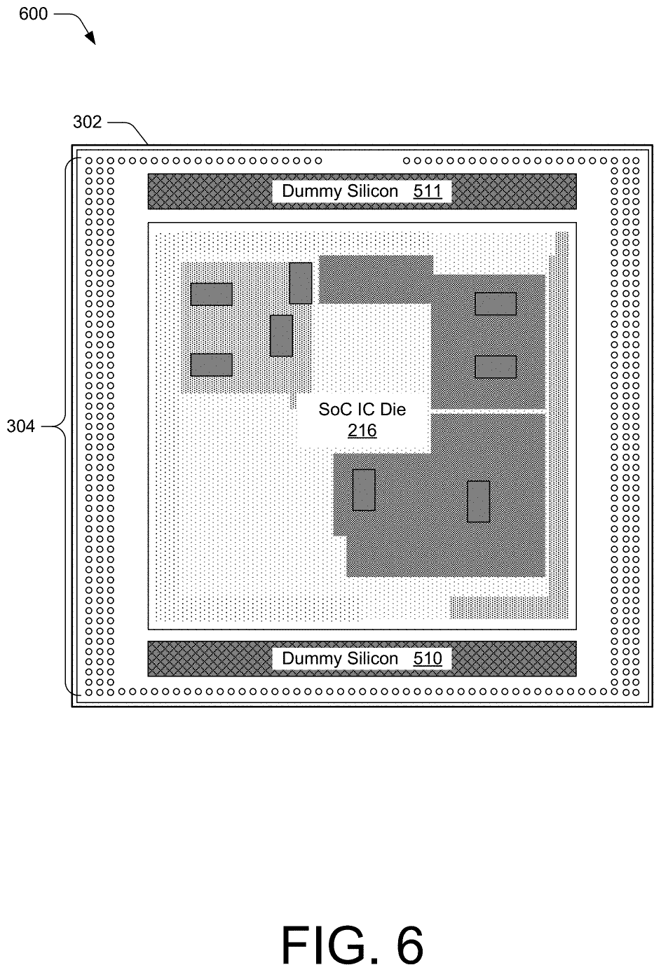

By way of example, consider FIG. 6, which illustrates at 600 a plan view of an example PoP assembly that includes dummy silicon components 510 and 511 encapsulated in an SoC IC package. This view may approximate a cross-section of the PoP assembly 104 of FIG. 5 in which the dummy silicon components 510 and 511 are shown relative to the first substrate 302 and solder interconnects 304 disposed around a periphery of the SoC IC die 214. As shown at 600, the dummy silicon may be disposed adjacent to the SoC IC die in the XY plane. In the illustrated example, the dummy silicon components 510 and 511 may be positioned on opposing sides of the SoC IC die in the XY plane. Furthermore, although two portions of dummy silicon are illustrated in FIGS. 5 and 6, any number of dummy silicon portions or components may be included (e.g., one, two, three, four, and so on) in an SoC IC package 106. Generally, the dummy silicon components 510, 511, and so forth spread heat originating with the SoC IC die 214 throughout the SoC IC package 106 for transfer to the memory IC package 108. This transfer of heat may include transferring the heat to an LPDDRS IC die of the memory IC package 108.

### Example Methods

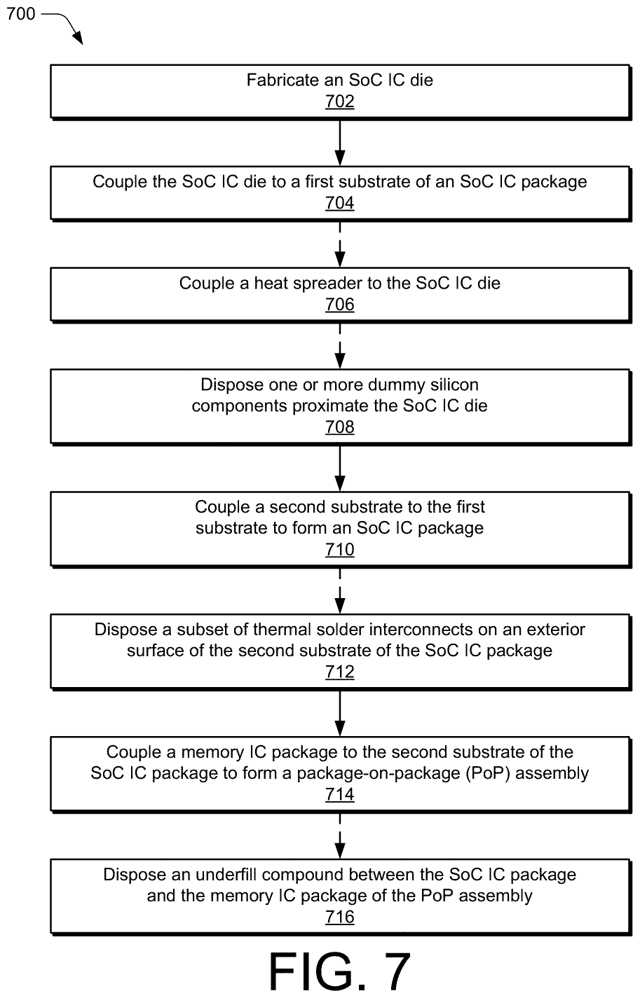

FIG. 7 illustrates example method(s) 700 for forming a PoP assembly with one or more thermal management components in accordance with one or more aspects. Generally, method(s) 700 illustrate sets of operations (or acts) performed in, but not necessarily limited to, the order or combinations in which the operations are shown herein. Further, any of one or more of the operations may be repeated, combined, reorganized, omitted, or linked to provide a wide array of additional and/or alternative methods for forming or fabricating a PoP assembly in accordance with various aspects. In portions of the following discussion, reference may be made to the example environment 100, example devices of FIG. 2, example PoP assemblies of FIGS. 3 through 6, and/or entities detailed in FIG. 1 or FIG. 2, reference to which is made for example only. The techniques and apparatuses described in this disclosure are not limited to embodiment or implementation in one entity or multiple entities of an IC package or chip assembly.

FIG. 7 illustrates example method(s) 700 for forming a PoP assembly with one or more thermal management components, which may include one or more of a heat spreader, dummy silicon component, or subset of solder interconnects. Generally, the method 700 may be implemented to provide a PoP assembly 104 with improved thermal management, which may enable increased IC die performance or improve IC die reliability. In some aspects, operations of the method 700 are implemented by or at respective IC, package, or assembly fabrication stages to provide a PoP assembly with improved thermal management, which may include a PoP assembly 104 as described with reference to FIGS. 1-6.

At 702, an SoC IC die is fabricated. For example, an SoC die may be fabricated to provide the SoC IC die as described herein, which may include the components or functionalities as described with reference to FIG. 2.

At 704, the SoC IC die is coupled to a first substrate. The first substrate may include an RDL configured with solder contacts to support solder interconnects that couple the SoC IC die to the first substrate. In some cases, the first substrate may include an embedded heat spreader or an external heat spreader coupled to an external surface of the first substrate.

Optionally at 706, a heat spreader is coupled to the SoC IC die. The heat spreader may be attached to the SoC IC die using a die attach film or other thermally conductive material. In aspects, the heat spreader and/or SoC IC package is configured as described with reference to FIG. 3.

Optionally at 708, one or more dummy silicon components are disposed proximate to the SoC IC die. For example, two dummy silicon components may be disposed adjacent to respective sides of the SoC IC die. In aspects, the dummy silicon components and/or SoC IC package are configured as described with reference to FIGS. 5 and 6.

At 710, a second substrate is coupled to at least the first substrate to form an SoC IC package. The second substrate may be coupled to the first substrate by a plurality of solder interconnects disposed between the first substrate and the second substrate. In some cases, the SoC IC die is in thermal contact with the second substrate. For example, the SoC IC die may be coupled to the second substrate using a die attach film or another thermally conductive material. Alternatively, a heat spreader of the SoC IC package may be in thermal contact with the second substrate of the SoC IC package.

Optionally at 712, a subset of thermal solder interconnects is disposed on an exterior surface of the second substrate of the SoC IC package. The subset of thermal solder interconnects may be implemented as part of a plurality of full array of solder interconnects disposed on the exterior surface of the SoC IC package. In aspects, the subset of thermal solder interconnect may be implemented as described with reference to FIG. 4.

At 714, a memory IC package is coupled to the SoC IC package to form a package-on-package assembly. The memory IC package may be coupled to a partial or full array of solder interconnects on an exterior surface of the SoC IC package. Alternatively, the solder interconnects may be coupled to the memory IC package prior to stacking the packages or disposed on the memory IC package or the SoC IC package during a packaging stacking assembly process.

Optionally at 716, an underfill compound is disposed between the SoC IC package and the memory IC package of the PoP assembly. In aspects, the underfill compound may displace air or another medium between the SoC IC package and the memory IC package. The underfill compound may have a thermal conductivity higher than air, such that the underfill compound improves the transfer of heat from the SoC IC package to the memory IC package.

Although implementations of a PoP assembly with improved thermal management are described, the subject of the appended claims is not necessarily limited to the specific features or methods described. Rather, the specific features and methods are disclosed as example implementations of a PoP assembly with improved thermal management.

### Variations

Although the above-described apparatuses and methods are described in the context of a PoP assembly with improved thermal management with reference to various examples, the described computing device, assemblies, systems, and methods are non-limiting and may apply to other contexts, chip configurations or assemblies, or other integrated system environments.

Generally, the components, modules, methods, and operations described herein can be implemented using software, firmware, automation, hardware (e.g., fixed logic circuitry), manual processing, or any combination thereof. Alternatively, or in addition, any of the configurations or functionalities described herein can be implemented, at least in part, to provide one or more types of chips or integrated systems, such as, and without limitation, SoCs, FPGAs, ASICs, ASSPs, SoCs, CPLDs, co-processors, context hubs, sensor co-processors, tensor processors, or the like. In the following, various examples are described.

A package-on-package (PoP) assembly comprising a first integrated circuit package comprising a first integrated circuit die; a second integrated circuit package comprising a second integrated circuit die, the second integrated circuit package coupled to the first integrated circuit package; and a thermal management component encapsulated in the first integrated circuit package and in thermal contact with the first integrated circuit die, the thermal management component comprising a heat spreader configured to spread heat from the first integrated circuit die throughout the first integrated circuit package to enable transfer of the heat to the second integrated circuit package.

In addition to the above-described PoP assembly, the first integrated circuit die may comprise a system-on-chip integrated circuit die; and the second integrated circuit die may comprise a memory integrated circuitry die.

In addition to the above-described PoP assembly, the heat spreader may comprise a copper material or a silicon material.

In addition to the above-described PoP assembly, the heat spreader may be configured with a thickness of approximately 50 micrometers; and/or the first silicon integrated circuit die may be configured with a thickness of approximately 50 micrometers.

In addition to the above-described PoP assembly, the first integrated circuit package may further comprise a die attach film disposed between the heat spreader and the first silicon integrated circuit die.

In addition to the above-described PoP assembly, the first integrated circuit package may further comprise a redistribution layer to electrically couple the first integrated circuit package to the second integrated circuit package; and the heat spreader may be disposed between the first integrated circuit die and the redistribution layer, the heat spreader being in thermal contact with the redistribution layer.

In addition to the above-described PoP assembly, a plurality of solder interconnects may be disposed between the first integrated circuit package and the second integrated circuit package, the plurality of solder interconnects including a subset of solder interconnects configured to transfer the heat from the first integrated circuit package to the second integrated circuit package.

In addition to the above-described PoP assembly, optionally, the subset of solder interconnects configured to transfer heat from the first integrated circuit package to the second integrated circuit package do not electrically couple the first integrated circuit package to the second integrated circuit package.

In addition to the above-described PoP assembly, the package-on-package assembly may comprise further thermal management components encapsulated in the first integrated circuit package, the further thermal management components including at least two dummy silicon components disposed adjacent to respective sides of the first silicon integrated circuit die and configured to spread heat from the first integrated circuit die throughout the first integrated circuit package to enable transfer of the heat to the second integrated circuit package.

In addition to the above-described PoP assembly, the redistribution layer may be a first redistribution layer and the first integrated circuit package may further comprise a second redistribution layer to which the first integrated circuit die is coupled to via an array of solder interconnects, and wherein the at least two dummy silicon components may be disposed between the first redistribution layer and the second redistribution layer.

In addition to the above-described PoP assembly, the second redistribution layer may comprise a heat transfer component configured to transfer heat from the array of solder interconnects coupled to the first integrated circuit die to another array of interconnects exposed on an exterior surface of the package-on-package assembly.

A PoP assembly comprising: a first integrated circuit package comprising a first integrated circuit die; a second integrated circuit package comprising a second integrated circuit die, the second integrated circuit package coupled to the first integrated circuit package; and thermal management components encapsulated in the first integrated circuit package, the thermal management components including at least two dummy silicon components disposed adjacent to respective sides of the first silicon integrated circuit die and configured to spread heat from the first integrated circuit die throughout the first integrated circuit package to enable transfer of the heat to the second integrated circuit package.

In addition to the above-described PoP assembly, the first integrated circuit die may comprise a system-on-chip integrated circuit die; and the second integrated circuit die includes a memory integrated circuit die.

In addition to the above-described PoP assembly, the PoP assembly may comprise a redistribution layer to electrically couple the first integrated circuit package to the second integrated circuit package; and a die attach film disposed between the first integrated circuit die and the redistribution layer, the die attach film in thermal contact with the redistribution layer and the first integrated circuit die.

In addition to the above-described PoP assembly, the redistribution layer may be a first redistribution layer and the first integrated circuit package may further comprise a second redistribution layer to which the first integrated circuit die is coupled to via an array of solder interconnects, and wherein the at least two dummy silicon components are disposed between the first redistribution layer and the second redistribution layer.

In addition to the above-described PoP assembly, the second redistribution layer may comprise a heat transfer component configured to transfer heat from the array of solder interconnects coupled to the first integrated circuit die to another array of interconnects exposed on an exterior surface of the package-on-package assembly.

In addition to the above-described PoP assembly, a plurality of solder interconnects may be disposed between the first integrated circuit package and the second integrated circuit package, the plurality of solder interconnects including a subset of solder interconnects configured to transfer heat from the first integrated circuit package to the second integrated circuit package.

In addition to the above-described PoP assembly, optionally, the subset of solder interconnects configured to transfer heat from the first integrated circuit package to the second integrated circuit package do not electrically couple the first integrated circuit package to the second integrated circuit package.

In addition to the above-described PoP assembly, the PoP assembly may further comprise a further thermal management component encapsulated in the first integrated circuit package and in thermal contact with the first integrated circuit die, the further thermal management component comprising a heat spreader configured to spread heat from the first integrated circuit die throughout the first integrated circuit package to enable transfer of the heat to the second integrated circuit package.

In addition to the above-described PoP assembly, the heat spreader may comprise a copper material or a silicon material.

In addition to the above-described PoP assembly, the heat spreader may be configured with a thickness of approximately 50 micrometers; and/or the first silicon integrated circuit die may be configured with a thickness of approximately 50 micrometers.

In addition to the above-described PoP assembly, the first integrated circuit package may further comprise a die attach film disposed between the heat spreader and the first silicon integrated circuit die.

In addition to the above-described PoP assembly, the first integrated circuit package may further comprise a redistribution layer to electrically couple the first integrated circuit package to the second integrated circuit package; and the heat spreader may be disposed between the first integrated circuit die and the redistribution layer, the heat spreader in thermal contact with the redistribution layer.

A PoP assembly comprising: a first integrated circuit package comprising a first integrated circuit die; a second integrated circuit package comprising a second integrated circuit die, the second integrated circuit package coupled to the first integrated circuit package; and thermal management components disposed between the first integrated circuit package and the second integrated circuit package, the thermal management components including a plurality of solder interconnects disposed between the first integrated circuit package and the second integrated circuit package, the plurality of solder interconnects including a subset of solder interconnects configured to transfer heat from the first integrated circuit package to the second integrated circuit package.

In addition to the above-described PoP assembly, a heat spreader configured to spread heat from the first integrated circuit die throughout the first integrated circuit package to enable transfer of the heat to the second integrated circuit package and/or at least two dummy silicon components disposed adjacent to respective sides of the first silicon integrated circuit die and configured to spread heat from the first integrated circuit die throughout the first integrated circuit package to enable transfer of the heat to the second integrated circuit package.

1. A package-on-package assembly comprising:
a first integrated circuit package comprising a first integrated circuit die;
a second integrated circuit package comprising a second integrated circuit die, the second integrated circuit package coupled to the first integrated circuit package; and
a thermal management component encapsulated in the first integrated circuit package and in thermal contact with the first integrated circuit die, the thermal management component comprising a heat spreader configured to spread heat from the first integrated circuit die throughout the first integrated circuit package to enable transfer of the heat to the second integrated circuit package.

2. The package-on-package assembly as recited in claim 1, wherein:
the first integrated circuit die comprises a system-on-chip integrated circuit die; and
the second integrated circuit die comprises a memory integrated circuitry die.

3. The package-on-package assembly as recited in claim 1, wherein the heat spreader comprises a copper material or a silicon material.

4. The package-on-package assembly as recited in claim 1, wherein:
the heat spreader is configured with a thickness of approximately 50 micrometers; or
the first integrated circuit die is configured with a thickness of approximately 50 micrometers.

5. The package-on-package assembly as recited in claim 1, wherein the first integrated circuit package further comprises a die attach film disposed between the heat spreader and the first integrated circuit die.

6. The package-on-package assembly as recited in claim 1, wherein:
the first integrated circuit package further comprises a redistribution layer to electrically couple the first integrated circuit package to the second integrated circuit package; and
the heat spreader is disposed between the first integrated circuit die and the redistribution layer, the heat spreader in thermal contact with the redistribution layer.

7. The package-on-package assembly as recited in claim 1, further comprising a plurality of solder interconnects disposed between the first integrated circuit package and the second integrated circuit package, the plurality of solder interconnects including a subset of solder interconnects configured to transfer the heat from the first integrated circuit package to the second integrated circuit package.

8. The package-on-package assembly as recited in claim 7, wherein the subset of solder interconnects configured to transfer heat from the first integrated circuit package to the second integrated circuit package do not electrically couple the first integrated circuit package to the second integrated circuit package.

9. The package-on-package assembly as recited in claim 1, further comprising:
additional thermal management components encapsulated in the first integrated circuit package, the additional thermal management components including at least two dummy silicon components disposed adjacent to respective sides of the first integrated circuit die and configured to spread heat from the first integrated circuit die throughout the first integrated circuit package to enable transfer of the heat to the second integrated circuit package.

10. A package-on-package assembly comprising:
a first integrated circuit package comprising a first integrated circuit die;
a second integrated circuit package comprising a second integrated circuit die, the second integrated circuit package coupled to the first integrated circuit package; and
thermal management components encapsulated in the first integrated circuit package, the thermal management components including at least two dummy silicon components disposed adjacent to respective sides of the first integrated circuit die and configured to spread heat from the first integrated circuit die throughout the first integrated circuit package to enable transfer of the heat to the second integrated circuit package.

11. The package-on-package assembly as recited in claim 10, wherein:
the first integrated circuit die comprises a system-on-chip integrated circuit die; and
the second integrated circuit die includes a memory integrated circuit die.

12. The package-on-package assembly as recited in claim 10, wherein the first integrated circuit package further comprises:
a redistribution layer to electrically couple the first integrated circuit package to the second integrated circuit package; and
a die attach film disposed between the first integrated circuit die and the redistribution layer, the die attach film in thermal contact with the redistribution layer and the first integrated circuit die.

13. The package-on-package assembly as recited in claim 12, wherein the redistribution layer is a first redistribution layer and the first integrated circuit package further comprises a second redistribution layer to which the first integrated circuit die is coupled to via an array of solder interconnects, and wherein the at least two dummy silicon components are disposed between the first redistribution layer and the second redistribution layer.

14. The package-on-package assembly as recited in claim 13, wherein the second redistribution layer comprises a heat transfer component configured to transfer heat from the array of solder interconnects coupled to the first integrated circuit die to another array of interconnects exposed on an exterior surface of the package-on-package assembly.

15. The package-on-package assembly as recited in claim 10, further comprising a plurality of solder interconnects disposed between the first integrated circuit package and the second integrated circuit package, the plurality of solder interconnects including a subset of solder interconnects configured to transfer heat from the first integrated circuit package to the second integrated circuit package.

16. The package-on-package assembly as recited in claim 15, wherein the subset of solder interconnects configured to transfer heat from the first integrated circuit package to the second integrated circuit package do not electrically couple the first integrated circuit package to the second integrated circuit package.

17. The package-on-package assembly as recited in claim 10, further comprising:
an additional thermal management component encapsulated in the first integrated circuit package and in thermal contact with the first integrated circuit die, the additional thermal management component comprising a heat spreader configured to spread heat from the first integrated circuit die throughout the first integrated circuit package to enable transfer of the heat to the second integrated circuit package.

18. The package-on-package assembly as recited in claim 17, wherein the heat spreader comprises a copper material or a silicon material.

19. The package-on-package assembly as recited in claim 17, wherein:
the heat spreader is configured with a thickness of approximately 50 micrometers; or
the first integrated circuit die is configured with a thickness of approximately 50 micrometers.

20. The package-on-package assembly as recited in claim 17, wherein the first integrated circuit package further comprises a die attach film disposed between the heat spreader and the first integrated circuit die.
